(19) United States
(12) Patent Application Publication
(10) Pub. No.: US 2014/0353647 A1
(43) Pub. Date: Dec. 4, 2014

(54) Organic Thin Film Transistors And Method of Making Them

(71) Applicant: CAMBRIDGE DISPLAY TECHNOLOGY LIMITED, Cambridgeshire (GB)

(72) Inventors: Christopher Newsome, Cambridgeshire (GB); Julian Carter, Cambridge (GB)

(73) Assignee: CAMBRIDGE DISPLAY TECHNOLOGY LIMITED, Cambridgeshire (GB)

(21) Appl. No.: 14/356,132

(22) PCT Filed: Oct. 29, 2012
(86) PCT No.: PCT/GB2012/000815

§ 371 Date: May 2, 2014

(30) Foreign Application Priority Data
Nov. 3, 2011 (GB) 1118997.4
Jan. 26, 2012 (GB) 1201291.0

(51) Int. Cl. H01L 51/05; H01L 51/00; H01L 51/10

(52) U.S. Cl. CPC H01L 51/0558; H01L 51/105; H01L 51/0021; H01L 51/0003; H01L 51/0026; H01L 51/0047; H01L 51/0035; H01L 51/0039
USPC 257/40; 438/99

(57) ABSTRACT

An organic thin film transistor comprises source and drain electrodes defining a channel between them; a surface-modification layer on at least part of the surface of each of the source and drain electrodes; an organic semiconductor layer extending across the channel and in contact with the surface-modification layers; a gate electrode; and a gate dielectric between the organic semiconductor layer and the gate dielectric. The surface-modification layers consist essentially of a partially fluorinated fullerene.

### FIELD OF THE INVENTION

The present invention relates to organic thin-film transistors (OTFTs) and methods of making OTFTs.

### BACKGROUND OF THE INVENTION

Transistors can be divided into two main types: bipolar junction transistors and field-effect transistors. Both types share a common structure comprising three electrodes with a semiconductive material disposed therebetween in a channel region. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as p-type and n-type according to whether they comprise semiconductive material which conducts positive charge carriers (holes) or negative charge carriers (electrons) respectively. The semiconductive material may be selected according to its ability to accept, conduct, and donate charge. The ability of the semiconductive material to accept, conduct, and donate holes or electrons can be enhanced by doping the material. The material used for the source and drain electrodes can also be selected according to its ability to accept and inject holes or electrons. For example, a p-type transistor device can be formed by selecting a semiconductive material which is efficient at accepting, conducting, and donating holes, and selecting a material for the source and drain electrodes which is efficient at injecting and accepting holes from the semiconductive material. Good energy-level matching of the Fermi-level in the electrodes with the HOMO (Highest Occupied Molecular Orbital) level of the semiconductive material can enhance hole injection and acceptance. In contrast, an n-type transistor device can be formed by selecting a semiconductive material which is efficient at accepting, conducting, and donating electrons, and selecting a material for the source and drain electrodes which is efficient at injecting electrons into, and accepting electrons from, the semiconductive material. Good energy-level matching of the Fermi-level in the electrodes with the LUMO (Lowest Unoccupied Molecular Orbital) level of the semiconductive material can enhance electron injection and acceptance.

Transistors can be formed by depositing the components in thin films to form thin-film transistors. When an organic material is used as the semiconductive material in such a device, it is known as an organic thin-film transistor (OTFT).

Various arrangements for OTFTs are known. One such device is an insulated gate field-effect transistor which comprises source and drain electrodes with a semiconductive material disposed therebetween in a channel region, a gate electrode disposed over the semiconductive material and a layer of insulting material disposed between the gate electrode and the semiconductive material in the channel region.

The conductivity of the channel can be altered by the application of a voltage at the gate. In this way the transistor can be switched on and off using an applied gate voltage. The drain current that is achievable for a given voltage is dependent on the mobility of the charge carriers in the organic semiconductor in the active region of the device (the channel region between the source and drain electrodes). Thus, in order to achieve high drain currents with low operational voltages, organic thin-film transistors must have an organic semiconductor which has highly mobile charge carriers in the channel region.

High mobility OTFTs containing “small molecule” organic semiconductor materials have been reported, and the high mobility has been attributed, at least in part, to the highly crystalline nature of the small molecule organic semiconductors in the OTFT. Particularly high mobilities have been reported in single crystal OTFTs wherein the organic semiconductor is deposited by thermal evaporation.

Formation of the semiconductor region by solution deposition of a blend of a small molecule organic semiconductor and a polymer is disclosed in Smith et. al., Applied Physics Letters, Vol 93, 253301 (2008); Russell et. al., Applied Physics Letters, Vol 87, 222109 (2005); Ohe et. al., Applied Physics Letters, Vol 93, 053303 (2008); Madec et. al., Journal of Surface Science & Nanotechnology, Vol 7, 455-458 (2009); Kang et. al., J. Am. Chem. Soc., Vol 130, 12273-75 (2008); Chung et al, J. Am. Chem. Soc. (2011), 133(3), 412-415; Lada et al, J. Mater. Chem. (2011), 21(30), 11232-11238; Hamilton et al, Adv. Mater. (2009), 21(10-11), 1166-1171; and WO 2005/055248.

Reducing contact resistance at the source and drain electrodes is disclosed in WO 2009/000683 by selectively forming a self-assembled layer of a dopant for the organic semiconductor on the surface of the source and drain electrodes.

EP 1950818 discloses an organic layer including a fluorine-containing compound between an anode and a hole injection layer of an OLED.

US 2005/0133782 discloses an OTFT comprising a nitrile layer arranged between the source and drain electrodes and the semiconductor. Nitriles disclosed include o-fluorobenzonitrile, p-fluorobenzonitrile, perfluorobenzonitrile and tetracyanoquinodimethane.

US 2010/0203663 discloses an OTFT comprising a thin self-assembled layer on the source and drain electrodes wherein the self-assembled material comprises a dopant moiety for doping an organic semiconductive material and a separate attachment moiety bonded to the dopant moiety and selectively bonded to the source and drain electrodes.

WO 2010/029542 discloses doping of organic semiconductors with fluorinated fullerene dopants by either mixing the dopant and the organic semiconductor in a solution or co-evaporation of the dopant and the organic semiconductor.

An object of the invention is to provide a low barrier to charge injection from source and drain electrodes to an organic semiconductor of an OTFT.

A further object of the invention is to provide a straightforward and controllable method of modifying the surface of an electrode to reduce a charge injection barrier.

A further object of the invention is to provide control over crystallization of organic semiconductors of an OTFT.

### SUMMARY OF THE INVENTION

In a first aspect the invention provides an organic thin film transistor comprising source and drain electrodes defining a channel therebetween; a surface-modification layer comprising a partially fluorinated fullerene on at least part of the surface of each of the source and drain electrodes; an organic semiconductor layer extending across the channel and in contact with the surface-modification layers; a gate electrode; and a gate dielectric between the organic semiconductor layer and the gate dielectric.

Optionally, the surface-modification layers are substantially free of any organic semiconductor doped by the partially fluorinated fullerene.

Optionally, the surface-modification layers consist essentially of the partially fluorinated fullerene.

Optionally, the source and drain electrodes are selected from a metal or metal alloy or a conductive metal oxide, optionally silver, gold, copper, nickel and alloys thereof.

Optionally, the source and drain electrodes comprise a material having a work function value that is closer to vacuum than a LUMO value of the partially fluorinated fullerene.

Optionally, the surface modification layers have a thickness of less than 10 nm, and are optionally a monolayer.

Optionally, the partially fluorinated fullerene is a partially fluorinated Buckminster fullerene, optionally a partially fluorinated C₆₀.

Optionally, the surface of at least one of the source and drain electrodes comprises a plurality of faces and wherein the surface modification layer is formed on at least two of the plurality of faces.

Optionally, the surface modification layer is formed on a face of the surface of one or both of the source and drain electrodes that faces the channel.

Optionally, the transistor is a top-gate transistor.

Optionally, the transistor is a bottom-gate transistor.

Optionally, the organic semiconducting layer comprises a polymer.

Optionally, the polymer comprises repeat units of formula (XI):

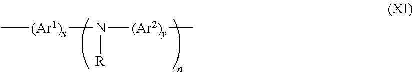

wherein Ar¹ and Ar² in each occurrence are independently selected from unsubstituted or substituted aryl or heteroaryl groups; n is greater than or equal to 1, preferably 1 or 2; R is H or a substituent; any of Ar¹, Ar² and R may be linked by a direct bond or linking group; and x and y are each independently 1, 2 or 3.

Optionally, the polymer comprises one or more unsubstituted or substituted arylene repeat units.

Optionally, the one or more substituted or unsubstituted arylene repeat units are selected from the group consisting of substituted or unsubstituted fluorene repeat units and substituted or unsubstituted phenylene repeat units.

Optionally, the organic semiconductor layer comprises a small molecule organic semiconductor.

Optionally, the small molecule organic semiconductor is selected from compounds of formulae (I)-(V):

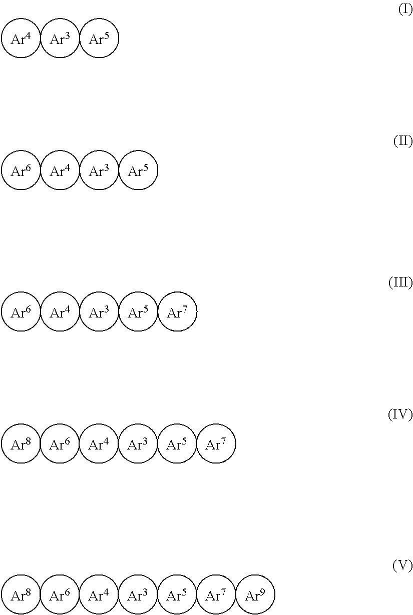

wherein Ar³, Ar⁴, Ar⁵, Ar⁶, Ar⁷, Ar⁸ and Ar⁹ are each independently selected from the group consisting of monocyclic aromatic rings and monocyclic heteroaromatic rings, and wherein Ar³, Ar⁴ and Ar⁵ may each optionally be fused to one or more further monocyclic aromatic or heteroaromatic rings.

Optionally, the partially fluorinated fullerene has formula CₐF_{b} wherein a is greater than b.

In a second aspect, the invention provides a method of forming an organic thin-film transistor according to the first aspect, the method comprising the steps of providing source and drain electrodes having a partially fluorinated fullerene on at least part of the surface of each of the source and drain electrodes, the source and drain electrodes defining the channel therebetween, and depositing at least one organic semiconducting material to form the organic semiconducting layer.

Optionally according to the second aspect, the method comprises the steps of depositing the partially fluorinated fullerene onto the source and drain electrodes to form the surface modification layers and depositing at least one organic semiconducting material onto the surface modification layer.

Optionally according to the second aspect, the surface modification layers are formed by depositing the partially fluorinated fullerene onto the source and drain electrodes from a partially fluorinated fullerene solution comprising the partially fluorinated fullerene and at least one solvent, and evaporating the at least one solvent.

Optionally according to the second aspect, the partially fluorinated fullerene solution is substantially free of any organic semiconductor capable of being doped by the partially fluorinated fullerene.

Optionally according to the second aspect, the partially fluorinated fullerene solution consists essentially of the partially fluorinated fullerene and the at least one solvent.

Optionally according to the second aspect, the organic semiconductor layer is formed by depositing an organic semiconductor solution comprising at least one organic semiconductor and at least one solvent onto the surface modification layers and evaporating the at least one solvent.

Optionally according to the second aspect, the organic semiconductor solution comprises one or both of a semiconducting polymer and a semiconducting small molecule.

Optionally according to the second aspect, the partially fluorinated fullerene is provided in the solution at a molar concentration of less than 0.1 M, optionally less than 0.01 M.

The invention will now be described in more detail with reference to the drawings in which:

### DESCRIPTION OF THE DRAWINGS

The invention will now be described in more detail with reference to the drawings in which:

FIG. 1A is a schematic illustration of a top-gate OTFT according to an embodiment of the invention;

FIG. 1B is a schematic illustration of a first bottom-gate OTFT according to an embodiment of the invention;

FIG. 1C is a schematic illustration of a second bottom-gate OTFT according to an embodiment of the invention;

FIG. 2A shows an AC-2 spectrum for a goldlayer treated with C₆₀F₃₆;

FIG. 2B shows an AC-2 spectrum for a comparative untreated gold layer;

FIG. 2C shows an AC-2 spectrum for a comparative gold layer treated with pentafluorobenzenethiol;

FIG. 3 shows an AC-2 spectrum for a silver layer treated with C₆₀F₃₆;

FIG. 4 shows an AC-2 spectrum for a silver layer treated with C₆₀F₄₈;

FIG. 5 shows an AC-2 spectrum for a gold layer treated with C₆₀F₄₈;

FIG. 6 is a graph of channel length vs. mobility for a range of channel lengths;

FIG. 7 shows a polarized optical microscope image of a semiconductor layer of a comparative device; and

FIG. 8 shows a polarized optical microscope image of a semiconductor layer of a device according to an embodiment of the invention.

### DETAILED DESCRIPTION OF THE INVENTION

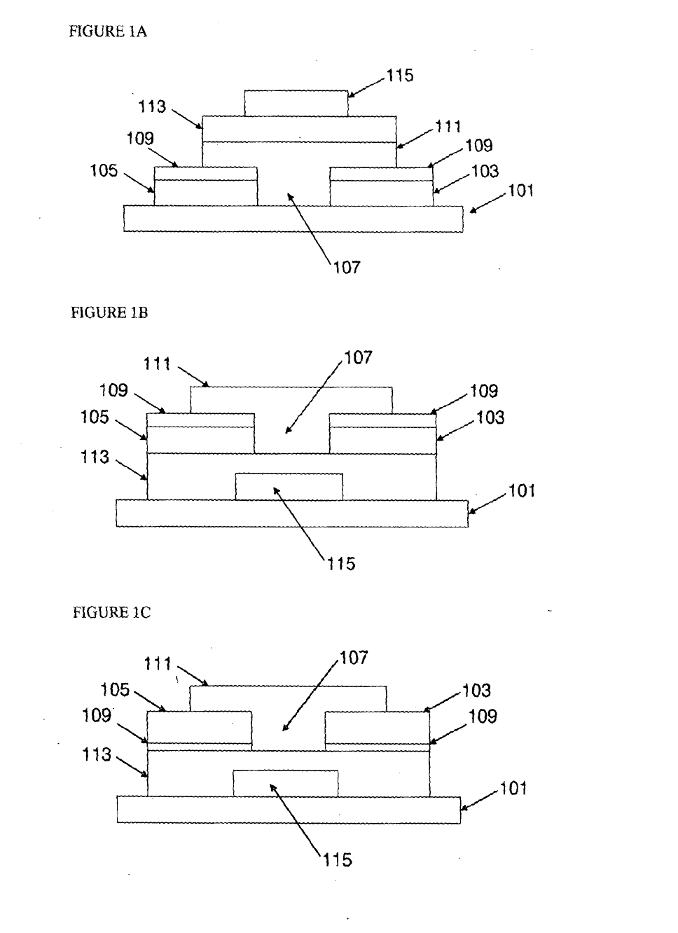

FIG. 1A, which is not drawn to any scale, schematically illustrates an exemplary top-gate organic thin-film transistor. The illustrated structure may be deposited on a substrate 101 and comprises source and drain electrodes 103, 105 which are spaced apart with a channel region 107 located therebetween. The channel may have a channel length between the source and drain electrodes of less than 500 microns, optionally less than 100 microns. The source and drain electrodes 103, 105 carry a surface modification layer 109. An organic semiconductor layer 111 in the channel region 107 is in contact with the surface modification layer 109, and may extend over at least some of the source and drain electrodes 103, 105. An insulating layer 113 of dielectric material is deposited over the organic semi-conductor layer 111 and may extend over at least a portion of the source and drain electrodes 103, 105. Finally, a gate electrode 115 is deposited over the insulating layer 113. The gate electrode 115 is located over the channel region 107 and may extend over at least a portion of the source and drain electrodes 103, 105. Further layers may be provided. For example, the base of the channel region may be treated with an organic material prior to deposition of the organic semiconductor.

The structure illustrated in FIG. 1A is known as a top-gate organic thin-film transistor as the gate is located on a top side of the device relative to a substrate. Alternatively, it is also known to provide the gate on a bottom side of the device to form a so-called bottom-gate organic thin-film transistor.

An example of a bottom-gate organic thin-film transistor is shown in FIG. 1B, which is not drawn to any scale. In order to show more clearly the relationship between the structures illustrated in FIGS. 1A and 1B, like reference numerals have been used for corresponding parts.

The bottom-gate structure illustrated in FIG. 1B, which is not drawn to any scale, comprises a gate electrode 115 deposited on a substrate 101 with an insulating layer 113 of dielectric material deposited thereover. Source and drain electrodes 103, 105 are deposited over the insulating layer 113 of dielectric material. The source and drain electrodes 103, 105 are spaced apart with a channel region 107 located therebetween over the gate electrode. An organic semiconductor layer 111 in the channel region 107 is in electrical contact with the surface modification layer 109, and may extend over at least a portion of the source and drain electrodes 103, 105.

FIG. 1C, which is not drawn to any scale, illustrates another bottom-gate structure, comprising elements as described with reference to FIG. 1B, except that the surface modification layer 109 is provided between the dielectric layer and the source and drain electrodes 103, 105.

The organic semiconductor layer in contact with the surface modification layer in any of FIG. 1A or 1B may have a HOMO of no more than 5.8 eV, optionally in the range of 4.5-5.7 eV, optionally in the range 5.3-5.4 eV. The HOMO level may be measured by photoelectron spectroscopy.

In FIGS. 1A, 1B and 1C, the surface modification layer 109 is illustrated as being present on an upper face only of the electrode on which it is present (an upper face in FIGS. 1A and 1B; a lower face in FIG. 1C), and fully covering that face. However, it will be appreciated that the surface modification layer may partially or fully cover any one face or more than one face of an exposed electrode surface. The surface modification layer may cover some or all of a face of the source and/or drain electrodes facing the channel. With reference to FIGS. 1A and 1B, upon deposition of a solution of the partially fluorinated fullerene over the channel and source and/or drain electrode surfaces, the partially fluorinated fullerene may selectively adhere to the exposed source and/or drain electrode faces that the solution comes into contact with, including one or both of electrode faces facing the channel and upper electrode faces.

### Partially Fluorinated Fullerene

The fullerene of the partially fluorinated fullerene may be any carbon allotrope in the form of a hollow sphere or ellipsoid.

The fullerene may consist of carbon atoms arranged in 5, 6 and/or 7 membered rings, preferably 5 and/or 6 membered rings. C₆₀ Buckminster Fullerene is particularly preferred.

The partially fluorinated fullerene may have formula CₐF_{b} wherein b is in the range of 10-60, optionally 10-50, and a is more than b. Examples include C₆₀F₁₈, C₆₀F₂₀, C₆₀F₃₆, C₆₀F₄₈, C₇₀F₄₄, C₇₀F₄₆, C₇₀F₄₈, and C₇₀F₅₄. Partially fluorinated fullerenes and their synthesis are described in more detail in, for example, Andreas Hirsch and Michael Brettreich, “Fullerenes: Chemistry and Reactions”, 2005 Wiley-VCH Verlag GmbH & Co KGaA, and in “The Chemistry Of Fullerenes”, Roger Taylor (editor) Advanced Series in Fullerenes—Vol. 4.

The partially fluorinated fullerene may consist of carbon and fluorine only or may include other elements, for example halogens other than fluorine and/or oxygen.

The partially fluorinated fullerene may have a LUMO level in the range of about −4.0 or deeper, optionally −4.0 to −5.0 eV as measured by cyclic voltammetry relative to a Saturated Calomel Electrode (SCE) in acetonitrile using tetraethylammonium perchlorate as supporting electrolyte, and assuming the Fermi energy level of SCE as 4.94 eV.

### Surface Modification Layer

The partially fluorinated fullerene may be deposited by any method known to the skilled person, including deposition from a solution of the partially fluorinated fullerene in at least one solvent followed by evaporation of the at least one solvent, and thermal evaporation of the partially fluorinated fullerene.

Solution processing methods include coating and printing methods. Exemplary coating methods include spin coating, dip-coating, slot die coating and doctor blade coating. Exemplary printing methods include inkjet printing, flexographic printing and gravure printing. By use of a solution processing method in which the source and drain electrodes are immersed in a solution of the partially fluorinated fullerene, it may be possible to coat all exposed faces of the source and drain electrodes. In particular, faces of the source and/or drain electrodes that face the channel may be coated.

Suitable solvents for partially fluorinated fullerenes include benzenes and naphthalenes substituted with one or more substituents selected from: halogen, for example chlorine; C₁₋₁₀ alkyl, for example methyl; and C₁₋₁₀ alkoxy, for example methoxy. Exemplary solvents include mono- or poly-chlorinated benzenes or naphthalenes, for example dichlorobenzene and 1-chloronaphthalene; benzene or naphthalene substituted with one or more methyl groups, for example toluene, o-xylene, m-xylene, 1-methylnaphthalene; and solvents substituted with more than one of a halogen, C₁₋₁₀ alkyl and C₁₋₁₀ alkoxy, for example 4-methylanisole. A single solvent or a mixture of more than one solvent may be used to deposit a partially fluorinated fullerene.

The thickness of the partially fluorinated film may be no more than 10 nm, optionally less than 5 nm, optionally a monolayer.

Without wishing to be bound by any theory, it is believed that the partially fluorinated fullerene forms a charge-transfer complex at the surface of the electrode material onto which it is deposited, resulting in an increase in workfunction at the resultant surface.

At lower thicknesses, in particular at monolayer thickness, substantially all of the partially fluorinated fullerene deposited onto the electrode surface may form a charge-transfer complex, in which case substantially all of the organic semiconductor/surface modification layer interface may be an interface between the charge-transfer complex and the organic semiconductor.

At higher thicknesses, the surface modification layer may include a charge-transfer complex layer part, for example a charge-transfer complex monolayer and, overlying the charge-transfer complex layer, a remainder layer part of fullerene that has not formed a charge transfer complex. Remaining fullerene that has not formed a charge-transfer complex may dope the organic semiconductor overlying the surface modification layer. Heating the organic semiconductor layer, which may take place after and/or during device manufacture, may increase the extent of doping of the organic semiconductor layer, particularly if the organic semiconductor material of the organic semiconductor layer is an amorphous material, for example a polymer. A heating temperature may be at least 60° C. Heating the organic semiconductor layer at a temperature above a glass transition temperature of the organic semiconductor material may increase the extent of doping.

Without wishing to be bound by any theory, it is believed that the presence of a substantial amount of partially fluorinated fullerene in the surface modification layer that has neither formed part of a charge-transfer complex nor doped the organic semiconductor may be detrimental to device performance. Accordingly, a surface modification layer having a thickness of no more than 10 nm may contain sufficient partially fluorinated fullerene to allow formation of a charge-transfer complex layer and optionally allow for doping of the organic semiconductor material by any remaining fullerene, without containing an amount of fullerene that may be detrimental to device performance.

Thickness of the surface modification layer may be controlled by evaporating a controlled amount of the partially fluorinated fullerene onto the surface of the source and drain electrodes.

The present inventors have found that the thickness of the surface modification layer may be controlled by deposition of the partially fluorinated fullerene from solution by, for example by one or more of:
(i) depositing a solution of a selected concentration of the partially fluorinated fullerene onto the surface of the source and drain electrodes, and/or
(ii) depositing a solution of the partially fluorinated fullerene onto the surface of the source and drain electrodes and then removing the solution from the surface of the electrodes before substantially all of the solvent has evaporated. Exemplary removal methods include rinsing using a rinsing solvent; blowing the solution off the electrode; and scraping the solution of the electrode. A solvent with a high boiling point may be used such that evaporation of the solvent, and associated precipitation of the partially fluorinated fullerene from solution, is slow. The solvent may have a boiling point of at least 200° C.

Formation of a thin (optionally no more than 10 nm) film of partially fluorinated fullerene may be obtained from a solution having a fluorinated fullerene molar concentration less than 0.1 M, optionally less than 0.01 M.

The partially fluorinated fullerene may selectively bind to the source and drain electrodes in which case the partially fluorinated fullerene may be applied over the source and drain electrodes using an indiscriminate deposition method, and partially fluorinated fullerene that does not come into contact with the exposed surface of the source or drain electrode may be removed by washing with a suitable solvent. For example, the partially fluorinated fullerene may be deposited from solution onto both a surface of the source and drain electrodes and a surface of the channel (which may be, for example, glass, plastic or a treated glass or plastic surface), and partially fluorinated fullerene in the channel may be washed away. Alternatively, the partially fluorinated fullerene may be selectively deposited onto the source and drain electrodes only. The presence of partially fluorinated fullerene in the channel may be detrimental to device performance, and so it is preferably removed, for example by washing, in the case of an indiscriminate deposition method or selectively deposited on the source and drain electrodes only.

### Source and Drain Electrodes

Suitable materials for forming the source and drain electrodes include a conductive electrode material wherein the LUMO level of the partially fluorinated fullerene is deeper than the workfunction of the conductive electrode material (for the avoidance of any doubt, “deeper” as used herein in the context of an energy level means further from vacuum level”).

Exemplary materials include metals and metal alloys, for example silver, gold, nickel, copper and alloys thereof, for example the silver-palladium-copper alloy APC; and conductive metal oxides, for example indium-tin oxide, and fluorinated tin oxide.

### Organic Semiconductor

Exemplary organic semiconductors include small molecule (i.e. non-polymeric) compounds having a core of at least three fused rings wherein each ring is independently selected from aromatic rings and heteroaromatic rings that may each individually be unsubstituted or substituted with one or more substituents, optionally with one or more solubilising substituents.

Small molecule compounds may be compounds having a polydispersity of 1, and may include dendrimers and oligomers (for example dimers, trimers, tetramers and pentamers).

Solubilising substituents may be substituents that increase solubility of the organic semiconductor in an organic solvent, for example a non-polar organic solvent, as compared to an unsubstituted organic semiconductor.

Optionally, the first small molecule organic semiconductor is selected from compounds of formulae (I)-(V) as described above.

Ar³, Ar⁴, Ar⁵, Ar⁶, Ar⁷, Ar⁸ and Ar⁹ may each independently be unsubstituted or substituted with one or more substituents.

Preferred substituents are X, which in each occurrence may be the same or different and may be selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups that may be unsubstituted or substituted with one, two or three alkyl groups having from 1 to 8 carbon atoms, silylethynyl groups that may be unsubstituted or substituted with one, two or three alkyl groups having from 1 to 8 carbon atoms and alkenyl groups having from 2 to 12 carbon atoms.

Optionally, at least one of Ar³, Ar⁴, Ar⁵, Ar⁶, Ar⁷, Ar⁸ and Ar⁹ comprises a 5- to 7-membered heteroaryl group containing from 1 to 3 sulfur atoms, oxygen atoms, selenium atoms and/or nitrogen atoms

The organic semiconductor may be an electron-rich compound, for example a compound comprising fused thiophene repeat units. Optionally, Ar³, Ar⁴, Ar⁵, Ar⁶, Ar⁷, Ar⁸ and Ar⁹ are each independently selected from phenyl and thiophene and wherein at least one of Ar³, Ar⁴, Ar⁵, Ar⁶, Ar⁷, Ar⁸ and Ar⁹ is thiophene.

The organic semiconductor may be selected from compounds of formulae (VI), (VII), (VIII), (IX) and (X):

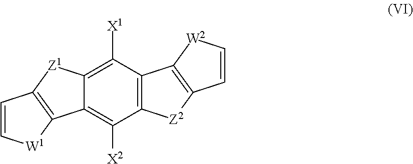

wherein X¹ and X² may be the same or different and are selected from substituents X as described above; Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

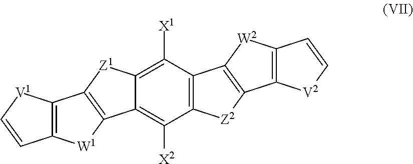

wherein X¹ and X² are as described with reference to formula (VI), Z¹, Z², W¹ and W² are as described with reference to formula (VI) and V¹ and V² are independently S, O, Se or NR⁵ wherein R⁵ is H or a substituent selected from the group consisting of substituted or unsubstituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

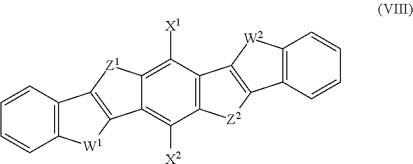

wherein X¹ and X², Z¹, Z², W¹ and W² are as described with reference to formula (VI).

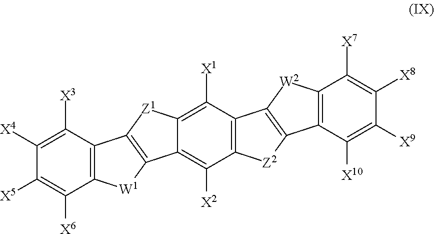

wherein Z¹, Z², W¹ and W² are as described with reference to formula (VI) and X¹-X¹⁰, which may be the same or different, are selected from substituents X as described above;

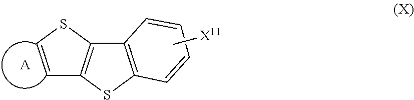

wherein A is a phenyl group or a thiophene group, said phenyl group or thiophene group optionally being fused with a phenyl group or a thiophene group which can optionally be fused with a group selected from a phenyl group, a thiophene group and a benzothiophene group, any of said phenyl, thiophene and benzothiphene groups being unsubstituted or substituted with at least one group of formula X¹¹; and

each group X¹¹ may be the same or different and is selected from substituents X as described above, and preferably is a group of formula CₙH₂ₙ₊₁ wherein n is an integer of from 1 to 20.

In the compound of formula (X), A is optionally selected from:

a thiophene group that is fused with a phenyl group substituted with at least one group of formula X¹¹; or

a phenyl group that may be unsubstituted or substituted with at least one group of formula X¹¹, said phenyl group further optionally being fused with a thiophene group which can be unsubstituted or substituted with at least one group of formula X¹¹ and/or fused with a benzothiophene group, said benzothiphene group being unsubstituted or substituted with at least one group of formula X¹¹, wherein X¹¹ is a group of formula CₙH₂ₙ₊₁ wherein n is an integer of from 1 to 16.

Compounds of formula (X) include the following:

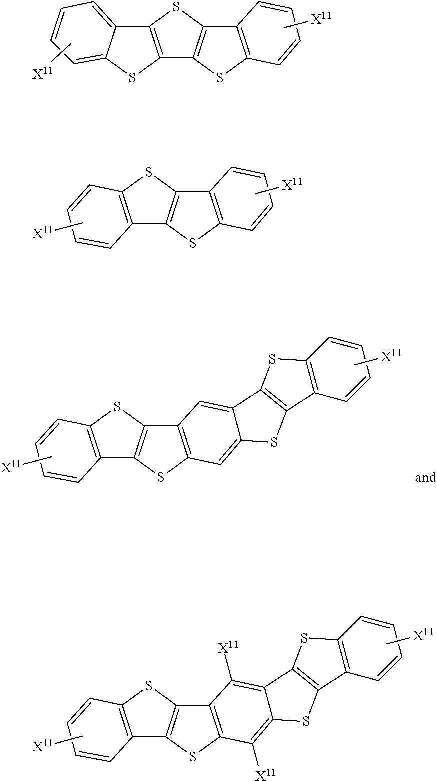

wherein X¹¹ is a group of formula CₙH₂ₙ₊₁ wherein n is an integer of from 1 to 16.

A preferred compound of formula (III) is pentacene substituted with one or more tri(C₁₋₁₀ alkyl)silylethynyl groups. Preferably, a tri(C₁₋₁₀ alkyl)silylethynyl substituent is provided in the 6- and 13-positions of pentacene. An exemplary substituted pentacene is 6,13-(tri-isopropyl-silylethynyl)pentacene (“TIPS pentacene”):

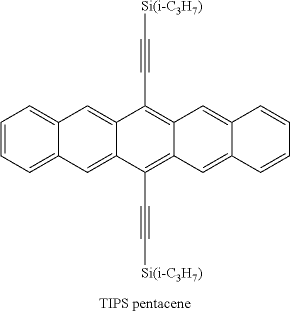

The one or more substituents of the organic semiconductor, for example substituents X and X¹-X¹¹ as described above, may be provided on: (a) one or both of the monocyclic aromatic or heteroaromatic rings at the end(s) of the organic semiconductor core; (b) on one or more of the monocyclic aromatic or heteroaromatic ring or rings that are not at the ends of the organic semiconductor core; or on both of (a) and (b).

The organic semiconducting layer may consist essentially of a small molecule organic semiconductor, or may comprise a blend of the small molecule organic semiconductor and one or more further materials. The organic semiconducting layer may comprise a blend of a small molecule organic semiconductor and a semiconducting or insulating polymer. Exemplary semiconducting polymers are described in more detail below.

The organic semiconductor may be deposited by any method known to the skilled person, for example by evaporation or, in the case of a soluble organic semiconductor, from a solution in one or more solvents.

### Polymers

The organic semiconductor layer of the OTFT may contain one or more semiconducting polymers.

The organic semiconductor layer may consist essentially of a semiconducting polymer or it may contain one or more further materials.

In preferred embodiments, the organic semiconductor layer is selected from one of: a layer consisting essentially of a semiconducting polymer; a layer comprising a semiconducting polymer wherein the only semiconducting material is the semiconducting polymer; and a layer comprising a blend of a semiconducting polymer and a small molecule organic semiconductor, for example a small molecule organic semiconductor as described above.

The semiconducting polymer may be a conjugated polymer. The semiconducting polymer may be a homopolymer or a co-polymer comprising two or more different repeat units.

A conjugated polymer may comprise repeat units selected from one or more of: substituted or unsubstituted (hetero)arylamine repeat units; substituted or unsubstituted heteroarylene repeat units; and substituted or unsubstituted arylene repeat units. The conjugated polymer may be a homopolymer or a copolymer comprising two or more different repeat units. An exemplary copolymer comprises one or more (hetero)arylamine repeat units, for example repeat units of formula (XI) described below, and one or more arylene repeat units, for example one or more fluorene and/or phenylene repeat units as described below.

Exemplary (hetero)arylamine repeat units may be selected from repeat units of formula (XI):

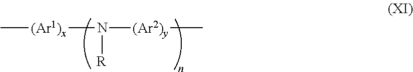

wherein Ar¹ and Ar² in each occurrence are independently selected from substituted or unsubstituted aryl or heteroaryl groups, n is greater than or equal to 1, preferably 1 or 2, R in each occurrence is H or a substituent, preferably a substituent, and x and y are each independently 1, 2 or 3.

Exemplary groups R include alkyl, Ar¹⁰, or a branched or linear chain of Ar¹⁰ groups, for example —(Ar¹⁰)ᵥ, wherein Ar¹⁰ in each occurrence is independently selected from aryl or heteroaryl and v is at least 1, optionally 1, 2 or 3.

Any of Ar¹, Ar² and Ar¹⁰ may independently be substituted with one or more substituents. Preferred substituents are selected from the group R³ consisting of:

alkyl wherein one or more non-adjacent C atoms may be replaced with O, S, substituted N, C═O and —COO— and one or more H atoms of the alkyl group may be replaced with F or aryl or heteroaryl which may be unsubstituted or substituted with one or more groups R⁸,

aryl or heteroaryl which may be unsubstituted or substituted with one or more groups R⁸,

NR⁹₂, OR⁹, SR⁹,

fluorine, nitro and cyano;

wherein each R⁸ is independently alkyl in which one or more non-adjacent C atoms may be replaced with O, S, substituted N, C═O and —COO— and one or more H atoms of the alkyl group may be replaced with F, and each R⁹ is independently selected from the group consisting of alkyl and aryl or heteroaryl which may be unsubstituted or substituted with one or more alkyl groups.

R may comprise a crosslinkable-group, for example a group comprising a polymerisable double bond such and a vinyl or acrylate group, or a benzocyclobutane group.

Any of the aryl or heteroaryl groups in the repeat unit of Formula (XI) may be linked by a direct bond or a divalent linking atom or group. Preferred divalent linking atoms and groups include O, S; substituted N; and substituted C.

Where present, substituted N or substituted C of R³, R⁸ or of the divalent linking group may independently in each occurrence be NR⁶ or CR⁶₂ respectively wherein R⁶ is alkyl or substituted or unsubstituted aryl or heteroaryl. Optional substituents for aryl or heteroaryl groups R⁶ may be selected from R⁸ or R⁹.

In one preferred arrangement, R is Ar¹⁰ and each of Ar¹, Ar² and Ar¹⁰ are independently unsubstituted or substituted with one or more C₁₋₂₀ alkyl groups.

Particularly preferred units satisfying Formula (XI) include units of Formulae I-3:

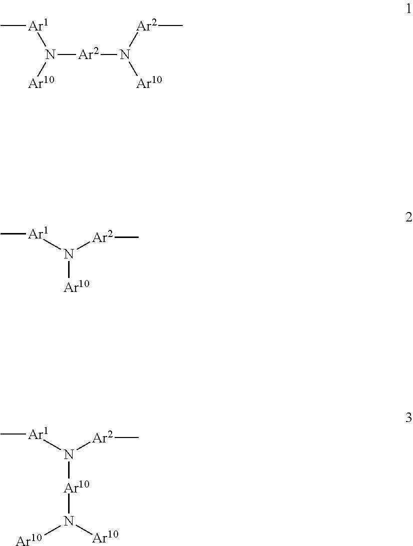

wherein Ar¹ and Ar² are as defined above; and Ar¹⁰ is unsubstituted or substituted aryl or heteroaryl. Where present, preferred substituents for Ar¹⁰ include substituents as described for Ar¹ and Ar², in particular alkyl and alkoxy groups.

Ar¹, Ar² and Ar¹⁰ are preferably phenyl, each of which may independently be substituted with one or more substituents as described above.

In another preferred arrangement, aryl or heteroaryl groups of formula (XI) are phenyl, each phenyl group being unsubstituted or substituted with one or more alkyl groups.

In another preferred arrangement, Ar¹, Ar² and Ar¹⁰ are phenyl, each of which may be substituted with one or more C₁₋₂₀ alkyl groups, and v=1.

In another preferred arrangement, Ar¹ and Ar² are phenyl, each of which may be substituted with one or more C₁₋₂₀ alkyl groups, and R is 3,5-diphenylbenzene wherein each phenyl may be substituted with one or more C₁₋₂₀ alkyl groups.

In another preferred arrangement, Ar¹, Ar² and Ar¹⁰ are phenyl, each of which may be substituted with one or more C₁₋₂₀ alkyl groups, n=1 and Ar¹ and Ar² are linked by O to form a phenoxazine group.

The polymer may comprise one, two or more different repeat units of formula (XI).

The polymer comprising repeat units of formula (XI) may be a homopolymer or a copolymer comprising repeat units other than repeat units of formula (XI). The repeat units of formula (XI) may be provided in any amount, for example in the range of about 1 mol % to about 70 mol %. In the case where the polymer is used as a light-emitting material, the repeat units of formula (XI) may be present in an amount less than 50 mol %, for example less than 20 mol % or less than 10 mol %.

Exemplary arylene repeat units include fluorene, indenofluorene, and phenylene repeat units, each of which may optionally be substituted by, for example, alkyl or alkoxy.

Exemplary fluorene repeat units include repeat units of formula (XII):

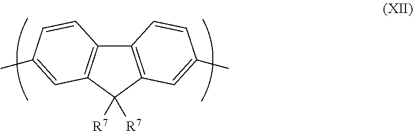

wherein the two groups R⁷, which may be the same or different, are each H or a substituent and wherein the two groups R⁷ may be linked to form a ring.

Each R⁷ is optionally selected from the group consisting of hydrogen; unsubstituted or substituted Ar¹⁰ or a linear or branched chain of Ar¹⁰ groups, wherein Ar¹⁰ is as described above with reference to formula (XI) and is preferably substituted or unsubstituted phenyl; and unsubstituted or substituted alkyl wherein one or more non-adjacent C atoms of the alkyl group may be replaced with O, S, substituted N, C═O and —COO—.

In the case where R⁷ comprises alkyl, optional substituents of the alkyl group include F, CN, nitro, and aryl or heteroaryl unsubstituted or substituted with one or more groups R⁸ wherein R⁸ is as described above with reference to formula (XI).

In the case where R⁷ comprises aryl or heteroaryl, each aryl or heteroaryl group may independently be substituted. Preferred optional substituents for the aryl or heteroaryl groups include one or more substituents R³ as described above with reference to formula (XI).

Optional substituents for the fluorene unit, other than substituents R⁷, are preferably selected from the group consisting of alkyl wherein one or more non-adjacent C atoms may be replaced with O, S, substituted N, C═O and —COO—; unsubstituted or substituted aryl, for example phenyl unsubstituted or substituted with one or more alkyl groups; unsubstituted or substituted heteroaryl; fluorine, cyano and nitro.

Where present, substituted N in repeat units of formula (XII) may independently in each occurrence be NR⁹ or NR⁶ wherein R⁶ and R⁹ are as described above with reference to formula (XI).

In one preferred arrangement, at least R⁷ comprises an unsubstituted or substituted C₁-C₂₀ alkyl or an unsubstituted or substituted aryl group, in particular phenyl substituted with one or more C₁₋₂₀ alkyl groups.

Repeat units of formula (XII) are optionally present in the polymer in an amount of at least 20 mol %, optionally at least 50 mol %, optionally more than 50 mol %.

Exemplary phenylene repeat units include repeat units of formula (XIII):

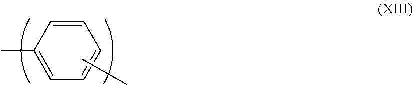

wherein the repeat unit of formula (XIII) may be substituted with one or more substituents R⁷ is as described above with reference to formula (XII). In one arrangement, the repeat unit is a 1,4-phenylene repeat unit.

The repeat unit of formula (XIII) may have formula (XIIIa), wherein R⁷ in each occurrence is a substituent and may be the same or different:

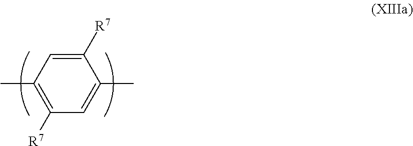

The polymer may be deposited from a solution in one or more solvents.

### Solution Processing

In the case where one or more layers of the OTFT are formed by solution processing, solution processing methods include coating and printing methods. Exemplary coating methods include spin coating, dip-coating, slot die coating and doctor blade coating. Exemplary printing methods include inkjet printing, flexographic printing and gravure printing.

Suitable solvents for soluble organic semiconductors, including soluble small molecule organic semiconductors and semiconducting polymers, may include benzenes substituted with one or more alkyl groups, for example one or more C₁₋₁₀ alkyl groups. Specific exemplary solvents include toluene and xylenes.

If a layer is formed by solution deposition onto an underlying layer that may be soluble in the solvent(s) used to deposit the layer then the underlying layer may be crosslinked prior to deposition of the solution. Alternatively or additionally, the solvent(s) for the solution may be selected from solvent(s) that do not dissolve the material(s) of the underlying layer.

### Gate Electrode

The gate electrode of an OTFT may be selected from a wide range of conducting materials for example a metal (e.g. gold or aluminium), metal alloy, metal compound (e.g. indium tin oxide) or conductive polymer.

Thickness of the gate electrode may be in the region of 5-200 nm as measured by Atomic Force Microscopy (AFM).

### Gate Insulating Layer

The gate insulating layer comprises a dielectric material selected from insulating materials having a high resistivity. The dielectric constant, k, of the gate dielectric is typically around 2-3 although materials with a high value of k are desirable because the capacitance that is achievable for an OTFT is directly proportional to k, and the drain current is directly proportional to the capacitance. Thus, in order to achieve high drain currents with low operational voltages, OTFTs with thin dielectric layers in the channel region are preferred. The thickness of the insulating layer is preferably less than 2 micrometres, more preferably less than 500 nm.

The gate dielectric material may be organic or inorganic. Preferred inorganic materials include SiO₂, SiₓN_{y}, silicon oxynitride and spin-on-glass (SOG). Organic dielectric materials include fluorinated polymers such as polytetrafluoroethylene (PTFE), perfluoro cyclo oxyaliphatic polymer (CYTOP), perfluoroalkoxy polymer resin (PFA), fluorinated ethylene-propylene (FEP), polyethylenetetrafluoroethylene (ETFE), polyvinylfluoride (PVF), polyethylenechlorotrifluoroethylene (ECTFE), polyvinylidene fluoride (PVDF), polychlorotrifluoroethylene (PCTFE), perfluoro elastomers (FFKM) such as Kalrez® or Tecnoflon®, fluoro elastomers such as Viton®, Perfluoropolyether (PFPE) and a polymer of tetrafluoroethylene, hexafluoropropylene and vinylidene fluoride (THV).

Non-fluorinated organic polymer insulator materials may also be used and include polymers such as poly vinylalcohol (PVA), polyvinylpyrrolidone, polyvinylphenol, acrylates such as polymethylmethacrylate (PMMA) and benzocyclobutanes (BCBs) available from Dow Corning. The insulating layer may be formed from a blend of materials. A multi-layered structure may be used in place of a single insulating layer.

The gate dielectric material may be deposited by thermal evaporation under vacuum or by lamination techniques as are known in the art. Alternatively, the dielectric material may be deposited from solution using, for example, spin coating or ink jet printing techniques and other solution deposition techniques discussed above.

If the dielectric material is deposited from solution onto the organic semiconductor layer, it should not result in dissolution of the organic semiconductor layer. Likewise, the dielectric material should not be dissolved if the organic semiconductor layer is deposited onto it from solution. Techniques to avoid such dissolution include: use of orthogonal solvents, that is use of a solvent for deposition of the uppermost layer that does not dissolve the underlying layer; and crosslinking of the underlying layer.

### Further Layers

Other layers may be included in the OTFT. For example, the surface of the channel region (that is, the region between the source and drain electrodes) may be provided with a monolayer comprising a material comprising a binding group and an organic group. Exemplary materials for such a monolayer include silanes, chloro- or alkoxy-silanes, for example a trichlorosilane substituted with a hydrocarbyl group selected from C₁₋₂₀ alkyl, phenyl and phenyl-C₁₋₂₀alkyl.

A material for modifying the surface of the channel region may selectively bind to the channel region such that the material may be applied over the channel and source and drain electrodes, and any material falling on the source and drain electrodes may be rinsed off.

An adhesion layer may be provided to bind the gate electrode and/or the source and drain electrodes to the underlying layer. For example, in the case of a top-gate OTFT a chromium adhesion layer may be provide between the substrate and the source and drain electrodes, and/or between the gate dielectric and the gate electrode.

### Encapsulation

OTFTs may be sensitive to moisture and oxygen. Accordingly, the substrate may have good barrier properties for prevention of ingress of moisture and oxygen into the device. The substrate is commonly glass, however alternative substrates may be used, in particular where flexibility of the device is desirable, for example a plastic substrate or a substrate of alternating plastic and barrier layers or a laminate of thin glass and plastic as disclosed in EP 0949850.

The device may been capsulated with an encapsulant to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

### EXAMPLES

### Example 1

C₆₀F₃₆ solutions were prepared to a concentration of 1 mM in anhydrous o-xylene (1.404 mg/ml) under a dry nitrogen environment. Vials of the solution were sealed, transported to air and subsequently heated to 60 degrees Celcius for a period of 60 minutes to ensure complete dissolution of the solid.

Glass substrates with gold electrodes (40 nm thick) were immersed in the C₆₀F₃₆ solution (at room temp) for a period of 5 minutes (substrates were not allowed to dry during this period). The C₆₀F₃₆ solution was removed from the solution and rinsed in o-xylene in order to remove excess C₆₀F₃₆ material from the substrate.

The work functions of the fullerene-treated material was measured by photoelectron spectroscopy using the AC-2 photoelectron spectrometer available from Riken Instruments Inc.

Measurements were performed in air, and produced plots of photoelectron yield vs. photon energy. The measurements were performed by probing a sample that is several square millimetres in area, and includes the following steps:
UV photons emitted from a deuterium lamp are monochromatized through the grating monochromator
The monocromatized UV photons at an intensity of 10 nW are focused on the modified surface
The energy of the UV photons is increased from 4.2 eV to 6.2 eV, in steps of 0.05 eV
When the energy of the UV photons is higher than the threshold energy of photoemission of the sample material (i.e. the Ionisation Potential), photoelectrons are emitted from the sample surface
Photoelectrons emitted from the sample are detected and counted in the air by an open air counter
Photoemission threshold (Work function) is determined from the energy of an intersecting point between a background line and an extrapolated line of the square root of the photoelectric quantum yield.

For the purpose of comparison AC-2 work function measurements were made of native gold (non-treated) contacts, and gold treated with pentafluorobenzenethiol.

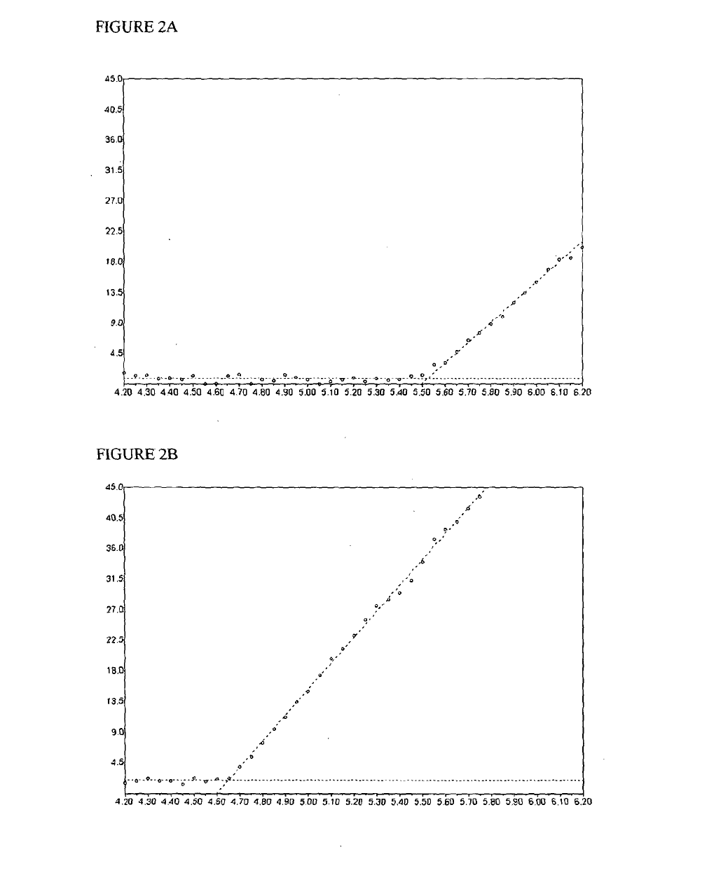

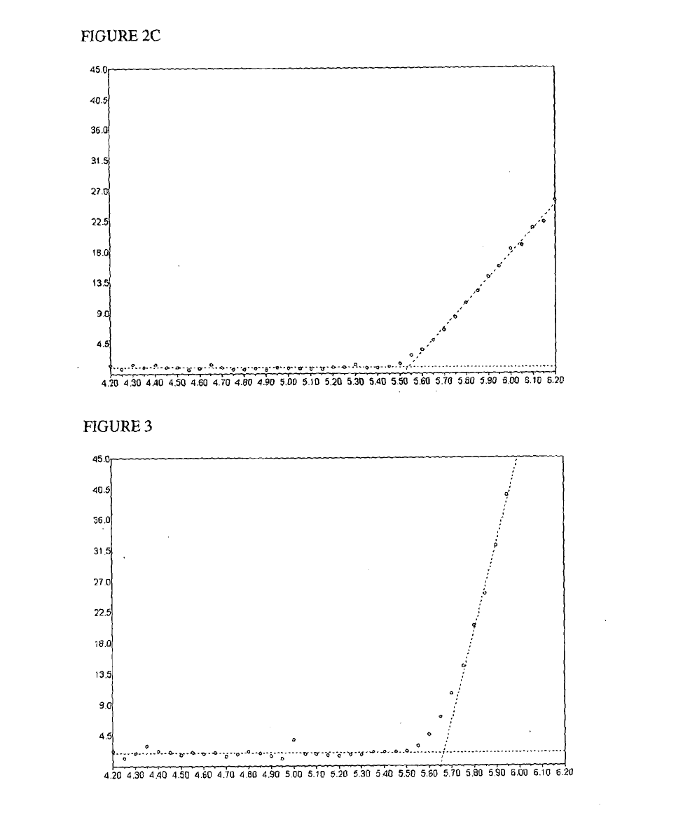

The results are summarized in Table 1 below, and AC-2 spectra are provided in FIGS. 2A-2C:

TABLE 1

| Example | Surface treatment | Work Function (eV) | Figure |
|---|---|---|---|
| Comparative | None- | 4.65 | 2B |
| Example 1 | | | |
| Comparative | Pentafluorobenzene | 5.55 | 2C |
| Example 2 | thiol- | | |
| Example 1 | C₆₀F₄₈ | 5.5 | 2A |

### Examples 3-5

A 0.03 weight % solution of a partially fluorinated fullerene selected from C₆₀F₃₆ and C₆₀F₄₈ was prepared.

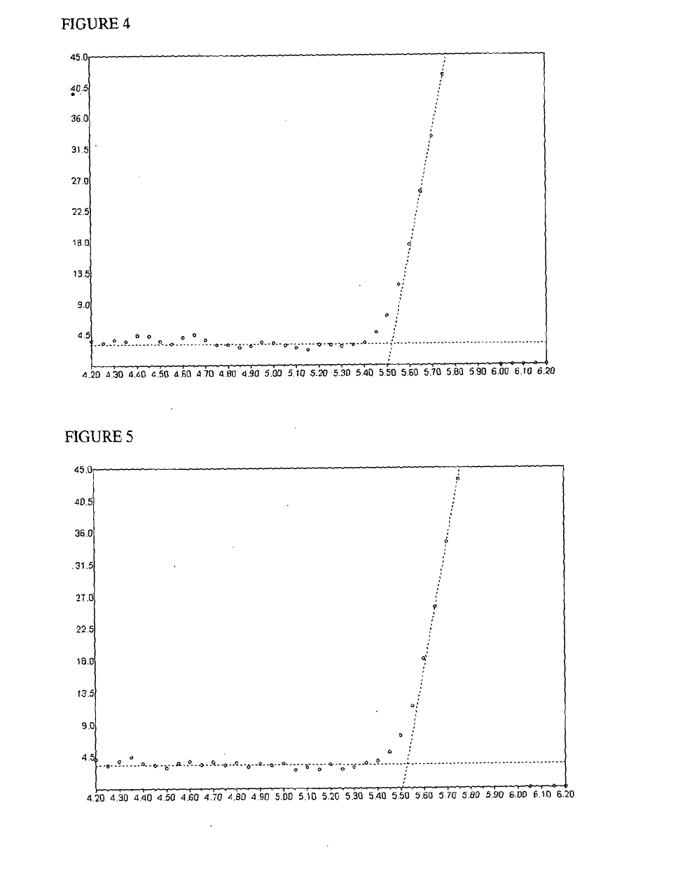

A substrate carrying a layer of silver or gold was immersed in the solution for approximately 1 minute and blown dry with a nitrogen gun. The results are summarized in Table 2 below, and the AC-2 spectra of Examples 3-5 are shown in FIGS. 3-5 respectively.

TABLE 2

| | | | Work | Signal |
|---|---|---|---|---|
| Example | Fullerene | Metal | Function (eV) | Gradient |
| 3 | C₆₀F₃₆ | Ag | 5.7 | 128.5 |
| 4 | C₆₀F₄₈ | Ag | 5.52 | 169.91 |
| 5 | C₆₀F₄₈ | Au | 5.53 | 178.85 |

### Device Example 1

Source and drain electrodes were formed on a glass substrate by patterning a photoresist layer and thermally evaporating a 5 nm adhesion layer of chrome and a 40 nm layer of gold. The Cr/Au bilayer was formed by removal of the photoresist layer to give source and drain electrodes defining a channel length of 5 microns. The surface of the source and drain electrodes was cleaned using oxygen plasma to remove residual photoresist.

The substrate carrying the source and drain electrodes was immersed in a 1 mM solution of C₆₀F₃₆ in ortho-xylene (1.4 mg per 1 ml solvent) for 5 minutes. The solution was removed by spinning the substrate on a spin coater and then rinsing it with o-xylene to remove any excess C₆₀F₃₆ solution. All of these steps were performed in air. Samples were then transported to a dry nitrogen environment and baked at 60° C. for 10 minutes.

A semiconducting composition of 25 wt % Small Molecule 1 and 75 wt % Polymer 1, illustrated below, was deposited onto the source and drain electrodes and the channel region by spin-coating an o-xylene solution of the composition with a concentration of 12 mg per 1 ml of solvent at 600 rpm for 60 seconds. The solution was deposited using an open bowl, allowing evaporation of the solvent during deposition. The resultant film was dried on a hotplate set at 100° C. for a period of 1 minute to remove the solvent from the film.

A 350 nm thick PTFE dielectric layer was deposited onto the organic semiconductor layer by spin-coating, and a 250 nm aluminium gate electrode was formed on the gate dielectric layer by thermal evaporation.

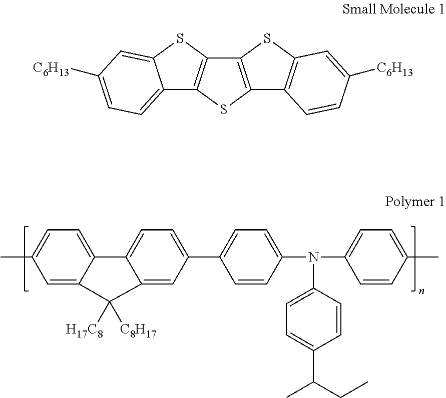

### Device Examples 2-6

Devices were prepared as described in Device Example 1 except that the channel length of Device Examples 2-6 was 10, 20, 30, 50 and 100 microns, respectively.

### Comparative Devices 1-6

For the purpose of comparison, Comparative Devices 1-6 were prepared as described for corresponding Device Examples 1-6 above except that the substrate carrying the source and drain electrodes was immersed in a solution of pentafluorobenzenethiol (PFBT), rather than C₆₀F₃₆, to form a monolayer of PFBT on the surface of the source and drain electrodes.

A number of each device example and each comparative device were prepared, and an average peak mobility for each device was determined.

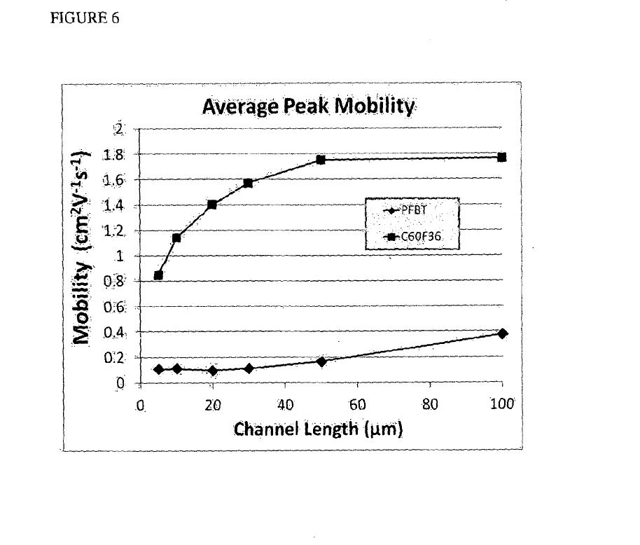

With reference to FIG. 6, the average peak mobility is higher for all devices treated with C₆₀F₃₆ as compared to comparative devices treated with PFBT.

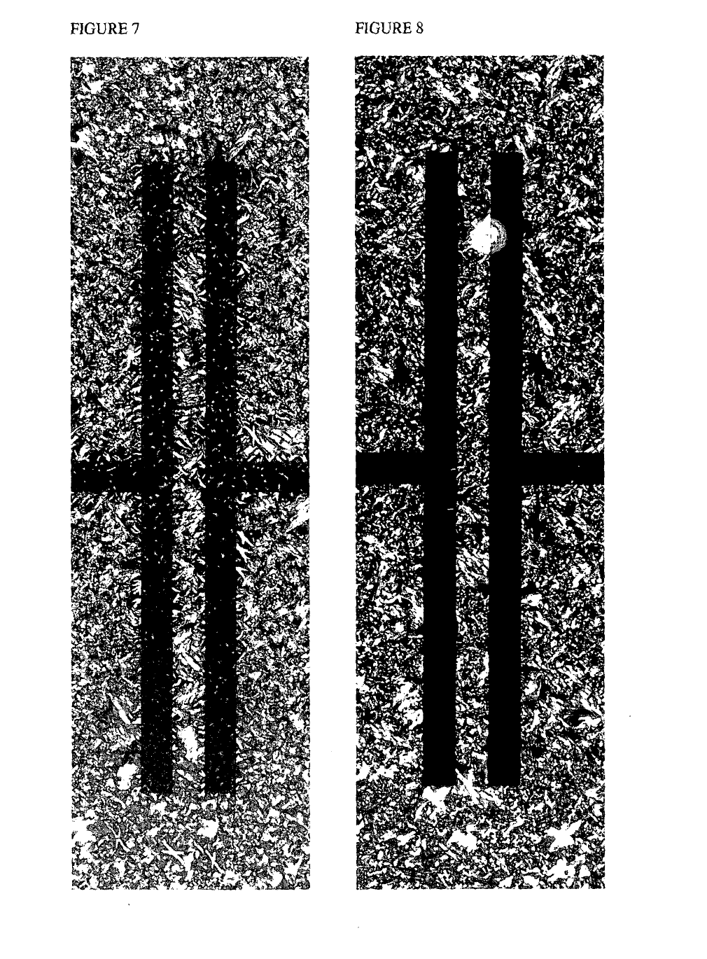

With reference to FIG. 7, which is an image of an organic semiconductor film formed on PFBT-treated source and drain electrodes, it can be seen that the morphology of the semiconductor film of a comparative device is not uniform in the channel between the electrodes, and in particular the morphology near the source and drain electrodes differs from morphology further from the source and drain electrodes. Again without wishing to be bound by any theory, use of organic semiconductors such as small molecules can result in a high density of organic semiconductor crystal nucleation centres forming at the metal surface. The consequence of such crystal nucleation centres being formed at the source and drain contacts may be smaller crystal domain sizes or depletion of the high mobility organic semiconductor material from the channel. In FIG. 7 regions of highly concentrated crystals are evident in the vicinity of the source-drain electrodes. These regions correspond to a high concentration of small molecule semiconductor with limited lateral crystal growth. The impact of this limited lateral crystal growth is that the channel region of the device can consist mostly of the low mobility polymer semiconductor. Again without wishing to be bound by any theory the mechanism for the crystal nucleation centres being formed may be due to a quadrupole interaction between the surface treatment material (a pentafluorobenzene in FIG. 7) and the conjugated semiconductor core.

With reference to FIG. 8, which is an image of an organic semiconductor film formed on C₆₀F₃₆-treated source and drain electrodes, deposition of a partially fluorinated fullerene results in formation of a film of substantially homogeneous morphology. Without wishing to be bound by any theory, using a bulky surface treatment molecule such as a partially fluorinated fullerene may reduce or eliminate the possibility for a quadrupole mediated interaction occurring between the surface treatment material and the organic semiconductor, and so may provide an OTFT having low contact resistance at the source and drain electrodes and a homogeneous organic semiconductor layer with high mobility in the channel region.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic thin film transistor comprising source and drain electrodes defining a channel therebetween; a surface-modification layer comprising a partially fluorinated fullerene on at least part of the surface of each of the source and drain electrodes; an organic semiconductor layer extending across the channel and in contact with the surface-modification layers; a gate electrode; and a gate dielectric between the organic semiconductor layer and the gate electrode.

2. An organic thin film transistor according to claim 1 wherein the surface-modification layers are substantially free of any organic semiconductor doped by the partially fluorinated fullerene.

3. An organic thin film transistor according to claim 1 wherein the surface-modification layers consist essentially of the partially fluorinated fullerene.

4. An organic thin film transistor according to claim 1 wherein the source and drain electrodes are selected from the group consisting of metals, metal alloys, and conductive metal oxides.

5. An organic thin film transistor according to claim 1 wherein the source and drain electrodes comprise a material having a work function value that is closer to vacuum than a LUMO value of the partially fluorinated fullerene.

6. An organic thin film transistor according to claim 1 wherein the surface modification layers have a thickness of less than 10 nm.

7. An organic thin film transistor according to claim 1 wherein the partially fluorinated fullerene is a partially fluorinated Buckminster fullerene.

8. An organic thin film transistor according to claim 1 wherein the surface of at least one of the source and drain electrodes comprises a plurality of faces and wherein the surface modification layer is formed on at least two of the plurality of faces.

9-11. (canceled)

12. An organic thin film transistor according to claim 1 wherein the organic semiconducting layer comprises a polymer.

13. An organic thin film transistor according to claim 12 wherein the polymer comprises repeat units of formula (XI): 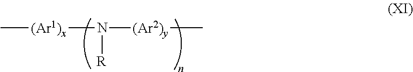
wherein Ar¹ and Ar² in each occurrence are independently selected from unsubstituted or substituted aryl or heteroaryl groups; n is greater than or equal to 1; R is H or a substituent; any of Ar¹, Ar² and R may be linked by a direct bond or linking group; and x and y are each independently 1, 2 or 3.

14. An organic thin film transistor according to claim 12 wherein the polymer comprises one or more unsubstituted or substituted arylene repeat units
wherein the one or more substituted or unsubstituted arylene repeat units are selected from the group consisting of substituted or unsubstituted fluorene repeat units and substituted or unsubstituted phenylene repeat units.

15. (canceled)

16. An organic thin film transistor according to claim 1 wherein the organic semiconductor layer comprises a small molecule organic semiconductor.

17-18. (canceled)

19. A method of forming an organic thin-film transistor according to claim 1, the method comprising the steps of providing source and drain electrodes having a partially fluorinated fullerene on at least part of the surface of each of the source and drain electrodes, the source and drain electrodes defining the channel therebetween, and depositing at least one organic semiconducting material to form the organic semiconducting layer.

20. A method according to claim 19 comprising the steps of depositing the partially fluorinated fullerene onto the source and drain electrodes to form the surface modification layers and depositing at least one organic semiconducting material onto the surface modification layers.

21. A method according to claim 20 wherein the surface modification layers are formed by depositing the partially fluorinated fullerene onto the source and drain electrodes from a partially fluorinated fullerene solution comprising the partially fluorinated fullerene and at least one solvent, and evaporating the at least one solvent.

22. A method according to claim 21 wherein the partially fluorinated fullerene solution is substantially free of any organic semiconductor capable of being doped by the partially fluorinated fullerene.

23. A method according to claim 22 wherein the partially fluorinated fullerene solution consists essentially of the partially fluorinated fullerene and the at least one solvent.

24. A method according to claim 20 wherein the organic semiconductor layer is formed by depositing an organic semiconductor solution comprising at least one organic semiconductor and at least one solvent onto the surface modification layers and evaporating the at least one solvent.

25. A method according to claim 24 wherein the organic semiconductor solution comprises one or both of a semiconducting polymer and a semiconducting small molecule.

26. A method according to claim 21 wherein the partially fluorinated fullerene is provided in the solution at a molar concentration of less than 0.1 M.
